(19) United States
(12) Patent Application Publication
(10) Pub. No.: US 2021/0193697 A1
(43) Pub. Date: Jun. 24, 2021

(54) DISPLAY DEVICE AND MANUFACTURING METHOD THEREOF

(71) Applicant: Samsung Display Co., Ltd., Yongin-Si (KR)

(72) Inventors: Dong Hwan KIM, Hwaseong-si (KR); Yun Seok LEE, Seoul (KR); Chang Woo KWON, Seoul (KR)

(21) Appl. No.: 16/918,759

(22) Filed: Jul. 1, 2020

(30) Foreign Application Priority Data
Dec. 20, 2019 (KR) 10-2019-0171815

(51) Int. Cl. H01L 27/12; H01L 29/786; G02F 1/1362; G02F 1/1343

(52) U.S. Cl. CPC H01L 27/1244; H01L 27/1222; H01L 27/1255; H01L 27/127; G02F 2001/136295; H01L 29/78696; G02F 1/136286; G02F 1/134309; H01L 27/1288

(57) ABSTRACT

A display device includes: a substrate; a gate insulating layer disposed on the substrate; a semiconductor layer disposed on the gate insulating layer and including a first semiconductor; a source electrode and a drain electrode disposed on the first semiconductor; and a data line disposed on the gate insulating layer, wherein the gate insulating layer includes a first portion overlapping the data line in a plan view and a second portion disposed adjacent to the first portion, and the second portion is thinner than the first portion.

### CROSS-REFERENCE TO RELATED APPLICATION

This application claims priority to and the benefit of Korean Patent Application No. 10-2019-0171815 filed in the Korean Intellectual Property Office on Dec. 20, 2019, the entire contents of which are incorporated herein by reference.

### BACKGROUND

### (a) Field of the Invention

The present disclosure relates to a display device and a manufacturing method of the display device.

### (b) Description of the Related Art

A display device such as a liquid crystal display (LCD), an organic light emitting diode (OLED) display, and the like includes a display panel including a plurality of pixels capable of displaying an image. Each pixel includes a pixel electrode receiving a data signal, and the pixel electrode is connected to at least one transistor to receive the data signal.

The transistor included in a pixel of the display panel may include a gate electrode, a semiconductor, a source electrode, and a drain electrode. A shape of the semiconductor may change depending on a manufacturing method of the transistor. For example, the semiconductor of the transistor may be patterned by using a single mask along with patterning of the source electrode and the drain electrode. Alternatively, the semiconductor of the transistor may be patterned separately from patterning of the source electrode and the drain electrode using a separate mask.

When patterning a semiconductor layer of a transistor along with patterning of a source electrode and a drain electrode, the semiconductor layer may remain under a data line and a quality defect such as horizontal crosstalk or a waterfall effect may occur by the semiconductor layer protruding outside an edge of the data line.

When patterning the semiconductor layer of the transistor by using a separate mask that is different from the mask used for patterning the source electrode and the drain electrode, a size of the transistor may be increased because an alignment margin between the semiconductor layer, and the source electrode and the drain electrode, should be sufficiently considered, and in a structure in which the transistors disposed in one pixel column are alternately connected to different data lines from each other, there may be a problem of a transverse line stain due to a kickback voltage distribution.

The above information disclosed in this Background section is for enhancement of understanding of the background of the present disclosure, and therefore it may contain information that does not form a prior art that is already known to a person of ordinary skill in the art.

### SUMMARY

The present disclosure provides a display device capable of preventing quality defects such as horizontal crosstalk or a waterfall effect, reducing a size of transistors, and reducing kickback voltage distribution.

A display device according to an embodiment of the present disclosure includes: a substrate; a gate insulating layer disposed on the substrate; a semiconductor layer disposed on the gate insulating layer and including a first semiconductor; a source electrode, and a drain electrode disposed on the first semiconductor; and a data line disposed on the gate insulating layer, wherein the gate insulating layer includes a first portion overlapping the data line in a plan view and a second portion disposed adjacent to the first portion, and the second portion is thinner than the first portion.

The first semiconductor may have an edge parallel to an edge of the source electrode and disposed outside the edge of the source electrode in the plan view.

The gate insulating layer may be disposed between the data line and the substrate, and the semiconductor layer may be absent in an area where the gate insulating layer is disposed between the data line and the substrate.

The display device may further include a gate line disposed on the substrate and crossing the data line, and the semiconductor layer may further include a second semiconductor disposed at a region where the gate line and the data line cross each other.

The source electrode may include a straight line portion extending in a direction different from an extending direction of the data line and a curved portion extending from the straight line portion, the semiconductor layer may further include a first protruded portion having a shape protruded from one side of the first semiconductor, and the first protruded portion of the semiconductor layer may overlap at least a part of the straight line portion of the source electrode.

The first protruded portion of the semiconductor layer may have an edge parallel to an edge of the part of the straight line portion of the source electrode.

The display device may further include a gate line disposed on the substrate and crossing the data line, the gate line may include a gate electrode, and the first protruded portion of the semiconductor layer may overlap an edge of the gate electrode.

The display device may further include a gate line disposed on the substrate and crossing the data line, the semiconductor layer may further include a second protruded portion having a shape protruded from one side of the first semiconductor, and the second protruded portion of the semiconductor layer may overlap an edge of the gate line.

The second protruded portion of the semiconductor layer may have an edge parallel to the edge of at least a first portion of the drain electrode away from a second portion that overlaps the first semiconductor.

The display device may further include a storage electrode disposed between the substrate and the gate insulating layer, wherein the drain electrode may include an expanded portion overlapping the storage electrode, and the semiconductor layer may be absent between the expanded portion and the substrate.

A display device according to an embodiment of the present disclosure includes: a substrate; a gate line disposed on the substrate; a gate insulating layer disposed on the gate line; a semiconductor layer disposed on the gate insulating layer and including a first semiconductor; a source electrode and a drain electrode that are disposed on the first semiconductor; and a data line disposed on the gate insulating layer, wherein the first semiconductor has an edge parallel to an edge of the source electrode and disposed outside the edge of the source electrode in a plan view, the semiconductor layer is absent between the data line and the substrate, and the semiconductor layer further includes a second semiconductor disposed at a region where the gate line and the data line cross each other.

The source electrode may include a straight line portion extending in a direction different from an extending direction of the data line and a curved portion extending from the straight line portion, the semiconductor layer may further include a first protruded portion having a shape protruded from one side of the first semiconductor, and the first protruded portion of the semiconductor layer may overlap at least a part of the straight line portion of the source electrode.

The first protruded portion of the semiconductor layer may have an edge parallel to an edge of the part of the straight line portion of the source electrode.

The gate line may include a gate electrode, and the first protruded portion of the semiconductor layer may overlap an edge of the gate electrode.

The semiconductor layer may further include a second protruded portion having a shape protruded from one side of the first semiconductor, and the second protruded portion of the semiconductor layer may overlap an edge of the gate line.

The second protruded portion of the semiconductor layer may have an edge parallel to an edge of at least a first portion of the drain electrode away from a second portion of the drain electrode that overlaps the first semiconductor.

A manufacturing method of a display device according to an embodiment of the present disclosure includes: forming a gate line including a gate electrode on a substrate; forming a gate insulating layer on the gate line; forming a semiconductor layer on the gate insulating layer and etching the semiconductor layer to form a first opening; depositing a conductive material on the semiconductor layer to form a conductive layer and etching the conductive layer by using a first mask pattern to form a data line and an electrode; and etching the semiconductor layer by using the first mask pattern or a second mask pattern that includes a portion of the first mask pattern, wherein the data line is formed at a position overlapping the first opening, and an edge of the first opening and an edge of the data line are spaced apart from each other.

The first mask pattern may include a first portion and a second portion having different thicknesses from each other, the second mask pattern may exclude the first portion that is thinner than the second portion, and the manufacturing method may further include etching the electrode by using the second mask pattern to form a source electrode and a drain electrode facing each other.

The manufacturing method of may further include forming a storage electrode line including a storage electrode on the substrate, wherein a second opening may be further formed in the semiconductor layer in the etching of the semiconductor layer to form the first opening, the drain electrode includes an expanded portion overlapping the storage electrode, the expanded portion may be formed at a position overlapping the second opening, and an edge of the second opening and an edge of the expanded portion of the drain electrode may be spaced apart from each other.

In the etching of the semiconductor layer by using the first mask pattern or the second mask pattern, a first semiconductor having an edge parallel to an edge of the source electrode and disposed outside the edge of the source electrode in a plan view may be formed.

According to an embodiment of the present disclosure, the display device may prevent occurrence of quality defects such as horizontal crosstalk or a waterfall effect, while reducing a size of the transistor and reducing a kickback voltage distribution.

### BRIEF DESCRIPTION OF THE DRAWINGS

FIG. 1 is a layout view of one pixel of a display device according to an embodiment of the present disclosure,

FIG. 2 is a cross-sectional view of the display device shown in FIG. 1 taken along a line IIa-IIb,

FIG. 3 is a cross-sectional view of the display device shown in FIG. 1 taken along a line IIIa-IIIb.

FIG. 4 is a layout view of a display device in an example process of a manufacturing method of a display device according to an embodiment of the present disclosure,

FIG. 5 is a cross-sectional view of the display device shown in FIG. 4 taken along a line Va-Vb,

FIG. 6 is a cross-sectional view of the display device shown in FIG. 4 taken along a line VIa-VIb,

FIG. 7 is a layout view of a display device in an example process at a later stage to that of the display device shown in FIG. 4,

FIG. 8 is a cross-sectional view of the display device shown in FIG. 7 taken along a line VIIIa-VIIIb,

FIG. 9 is a cross-sectional view of the display device shown in FIG. 7 taken along a line IXa-IXb,

FIG. 10 is a layout view of a display device in an example process at a later stage to that of the display device shown in FIG. 7,

FIG. 11 is a cross-sectional view of the display device shown in FIG. 10 taken along a line XIa-XIb,

FIG. 12 is a cross-sectional view of the display device shown in FIG. 10 taken along a line XIIa-XIIb,

FIG. 13 is a layout view of the display device in an example process at a later stage to that of the display device shown in FIG. 11,

FIG. 14 is a layout view of a display device in an example process at a later stage to that of the display device shown in FIG. 12,

FIG. 15 is a layout view of a display device in an example process at a later stage to that of the display device shown in FIG. 10,

FIG. 16 is a cross-sectional view of the display device shown in FIG. 15 taken along a line XVIa-XVIb,

FIG. 17 is a cross-sectional view of the display device shown in FIG. 15 taken along a line XVIIa-XVIIb,

FIG. 18 is a layout view of a display device in an example process at a later stage to that of the display device shown in FIG. 15,

FIG. 19 is a cross-sectional view of the display device shown in FIG. 18 taken along a line XIXa-XIXb,

FIG. 20 is a cross-sectional view of the display device shown in FIG. 18 taken along a line XXa-XXb,

FIG. 21 is a layout view of a display device in an example process of a manufacturing method of a display device according to an embodiment of the present disclosure,

FIG. 22 is a layout view of a pixel of a display device according to an embodiment of the present disclosure,

FIG. 23 is a cross-sectional view of surroundings of a data line of a display device according to an embodiment of the present disclosure, and

FIG. 24 is a layout view of a display device according to an embodiment of the present disclosure.

### DETAILED DESCRIPTION OF THE EMBODIMENTS

The present disclosure will be described more fully hereinafter with reference to the accompanying drawings, in which exemplary embodiments of the present disclosure are shown. As those skilled in the art would realize, the described exemplary embodiments may be modified in various different ways, without departing from the spirit or scope of the present disclosure.

In order to clearly explain the present disclosure, portions that are not directly related to the present disclosure may be omitted, and the same reference numerals may be used to reference the same or similar constituent elements through the present disclosure.

In addition, the size and thickness of each configuration shown in the drawings are arbitrarily shown for better understanding and ease of description, but the present disclosure is not limited thereto. In the drawings, the thickness of layers, films, panels, regions, etc., may be exaggerated for clarity. In the drawings, for better understanding and ease of description, the thicknesses of some layers and areas may be exaggerated.

It will be understood that when an element such as a layer, film, region, or substrate is referred to as being “on” another element, it can be directly on the other element or one or more intervening elements may also be present. In contrast, when an element is referred to as being “directly on” another element, there are no intervening elements present. Further, in the present disclosure, the word “on” or “above” means positioned on or below an object portion, and does not necessarily mean positioned on the upper side of the object portion based on a gravitational direction.

In addition, unless explicitly described to the contrary, the word “comprise” and its variations such as “comprises” or “comprising” will be understood to imply inclusion of stated elements but not exclusion of any other elements.

Throughout the present disclosure and the claims that follow, a plan view means a view when observing a surface parallel to two directions (e.g., a first direction DR1 and a second direction DR2) crossing each other, and a cross-sectional view means a view when observing a surface cut in a third direction (e.g., a direction DR3) perpendicular to the surface parallel to the first and second directions DR1 and DR2. In addition, to overlap two constituent elements means that two constituent elements are overlapped in the third direction (e.g., a direction perpendicular to an upper surface of the substrate) unless explicitly stated otherwise.

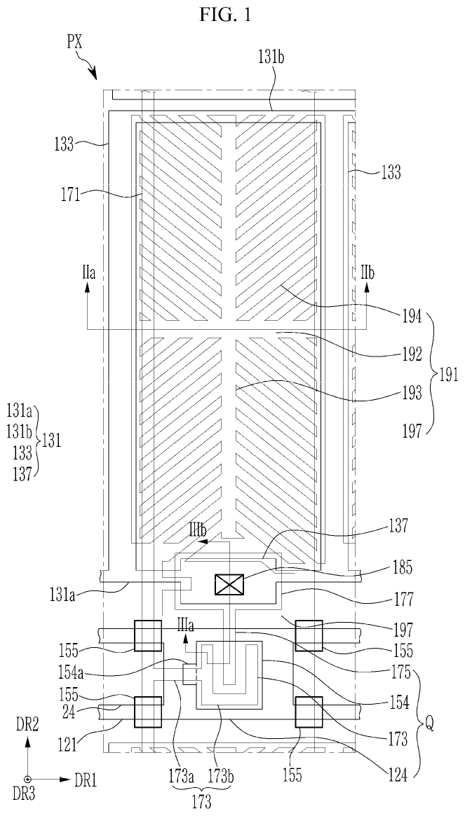

First, a display device according to an embodiment of the present disclosure is described with reference to FIG. 1 to FIG. 3.

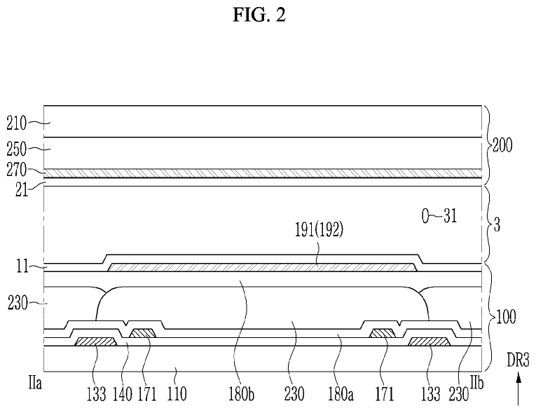

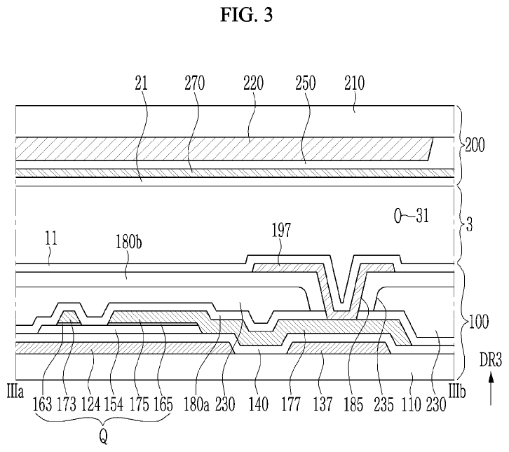

FIG. 1 is a layout view of one pixel of a display device according to an embodiment of the present disclosure, FIG. 2 is a cross-sectional view of the display device shown in FIG. 1 taken along a line IIa-IIb, and FIG. 3 is a cross-sectional view of the display device shown in FIG. 1 taken along a line IIIa-IIIb.

The display device according to an embodiment of the present disclosure includes a plurality of pixels PX, and each pixel PX may include a display element capable of displaying an image and a pixel circuit including at least one transistor.

The display device may be various types of display devices such as a liquid crystal display, an organic light emitting diode (OLED) display, an electrophoretic display, an electrowetting display device, a micro light emitting diode (LED) (Micro LED) display device, a quantum light emitting diode (QLED) display, and a quantum organic light emitting diode (QD-OLED) display. In the present description, a liquid crystal display is described as an example of the display device.

The display device includes a first substrate 110, and the display element and the pixel circuit may be formed on the first substrate 110.

A gate conductive layer including a plurality of gate lines 121 may be disposed on the first substrate 110.

Each gate line 121 may transmit a gate signal and may extend in a direction substantially parallel to the first direction DR1. Each gate line 121 may include a plurality of gate electrodes 124.

The gate line 121 may have an opening 24 disposed between two gate electrodes 124 adjacent in the first direction DR1.

The gate conductive layer may also include a plurality of storage electrode lines 131. The storage electrode line 131 is spaced apart from the gate line 121 and may transmit a constant voltage. The storage electrode line 131 may include a first transverse portion 131a, a second transverse portion 131b, an expanded portion 137, and a longitudinal portion 133.

The first transverse portion 131a may extend in a direction substantially parallel to the first direction DR1.

The first transverse portion 131a may be connected to the expanded portion 137 disposed in the pixel PX. The expanded portion 137 may be also referred to as a storage electrode.

The longitudinal portion 133 may extend substantially in the second direction DR2 from the first transverse portion 131a. The longitudinal portion 133 may be disposed at both left and right sides of the pixel PX.

The second transverse portion 131b is spaced from the first transverse portion 131a and may extend substantially in the first direction DR1. The longitudinal portion 133 may be disposed between the first and second transverse portions 131a and 131b and connected to the first and second transverse portions 131a and 131b.

A gate insulating layer 140 may be disposed on the gate conductive layer. The gate insulating layer 140 may include an insulating material such as silicon nitride (SiNx), silicon oxide (SiOx), silicon oxynitride, etc.

A semiconductor layer including a semiconductor 154 may be disposed on the gate insulating layer 140. The semiconductor layer may include a semiconductor material such as amorphous silicon, polycrystalline silicon, a metal oxide, etc.

The semiconductor 154 is disposed above the gate electrode 124 and may overlap at least a portion of the gate electrode 124 in a plan view (or, in a direction perpendicular to the upper surface of the first substrate 110).

Ohmic contact layers 163 and 165 may be disposed on the semiconductor layer.

The ohmic contact layers 163 and 165 may include n+ hydrogenated amorphous silicon or a silicide in which n-type impurities such as phosphorous are heavily doped.

A data conductive layer may be disposed on the ohmic contact layers 163 and 165 and the gate insulating layer 140. The data conductive layer may include a plurality of data lines 171, a plurality of source electrodes 173, and a plurality of drain electrodes 175.

Each data line 171 may transmit a data voltage and may substantially extend in a direction parallel to the second direction DR2, thereby crossing the gate line 121.

The source electrode 173 disposed in the pixel PX is electrically connected to each corresponding data line 171, thereby receiving the data voltage. The source electrode 173 may have a straight line portion 173a extending in a direction substantially parallel to the first direction DR1 from the corresponding data line 171, and a curved portion 173b connected to the straight line portion 173a. The curved portion 173b may be curved, for example, in a substantially U letter shape, and overlap the gate electrode 124. However, the shape of the source electrode 173 is not limited to the U letter shape.

The drain electrode 175 is spaced apart from the data line 171 and the source electrode 173.

The drain electrode 175 may include a bar-shape portion including one end portion facing the source electrode 173 and surrounded by the curved portion 173b of the source electrode 173 in a region overlapping the gate electrode 124 and the semiconductor 154. The drain electrode 175 may include an expanded portion 177 disposed at the other end of the bar-shape portion. The expanded portion 177 may be disposed above the gate line 121 in a plan view.

In a plan view, the expanded portion 177 of the drain electrode 175 may overlap the expanded portion 137 of the storage electrode line 131. The expanded portion 177 of the drain electrode 175 and the expanded portion 137 of the storage electrode line 131 that overlap each other via the gate insulating layer 140 interposed therebetween may form a storage capacitor capable of storing a charge voltage of the pixel PX.

The opening 24 of the gate line 121 overlaps the data line 171 crossing the gate line 121, thereby reducing a signal delay due to coupling between the gate line 121 and the data line 171.

The ohmic contact layers 163 and 165 exist only between the underlying semiconductor 154 below and the overlying data conductive layer thereon and may lower the contact resistance therebetween.

At least one of the gate conductive layer and the data conductive layer may include at least one among metals such as copper (Cu), aluminum (Al), magnesium (Mg), silver (Ag), gold (Au), platinum (Pt), palladium (Pd), nickel (Ni), neodymium (Nd), iridium (Ir), molybdenum (Mo), tungsten (W), titanium (Ti), chromium (Cr), tantalum (Ta), and alloys thereof.

The gate electrode 124, the source electrode 173, and the drain electrode 175 form a transistor Q (e.g., a thin film transistor) of a switching element along with the semiconductor 154. The channel of the transistor Q is formed in the semiconductor 154 between the source electrode 173 and the drain electrode 175. The transistor Q is included in the pixel circuit of the pixel PX.

In an embodiment of the present disclosure, a plan shape of the semiconductor 154 has an edge that is substantially parallel to an outer edge of the source electrode 173 facing the drain electrode 175 via the channel interposed therebetween, and disposed outside the outer edge of the source electrode 173. In detail, the semiconductor 154 may include an edge extending substantially parallel to an outer envelope of the curved portion 173b of the source electrode 173 and disposed outside the outer envelope.

In one embodiment, the spatial gap between the edge of the semiconductor 154 and the outer part of the source electrode 173 may be substantially 0.5 micrometers to 2.5 micrometers. In some embodiments, the spatial gap between the edge of the semiconductor 154 and the outer of the source electrode 173 may be substantially constant.

The semiconductor layer may include a protruded portion 154a overlapping a portion adjacent to the curved portion 173b among the straight line portion 173a of the source electrode 173. The protruded portion 154a may have an edge parallel to the edge of the part adjacent to the curved portion 173b among the straight line portion 173a of the source electrode 173 and disposed outside thereof. The protruded portion 154a may have a shape protruded from one side of the semiconductor 154. In some embodiments, the protruded portion 154a may be omitted.

Referring to FIG. 1, the semiconductor layer may include a semiconductor 155 having an island shape and disposed where the data line 171 and the gate line 121 overlap and cross each other. The semiconductor 155 may include an edge substantially parallel to the edge of the data line 171.

A short circuit defect may occur between the data line 171 and the gate line 121 due to a step of the gate line 121 at the portion where the data line 171 overlaps the gate line 121. However, according to the present embodiment, since the semiconductor 155 is disposed at a crossing region of the gate line 121 and the data line 171, the short circuit defect between the data line 171 and the gate line 121 may be prevented.

According to the present embodiment, the semiconductor layer may not be disposed under the data line 171 and the expanded portion 177 of the drain electrode 175, and the data line 171 and the expanded portion 177 of the drain electrode 175 may not overlap the semiconductor layer. Also, no semiconductor layer is formed outside an edge of the data line 171 and the expanded portion 177 of the drain electrode 175. Therefore, defects affecting the quality of the display device such as horizontal crosstalk or a waterfall effect that may be caused by parasitic capacitors and photoreactions and occur when the semiconductor layer protrudes out of the edge of the data line 171 and the expanded portion 177 of the drain electrode 175 may be prevented.

Simultaneously, the semiconductor 154 including a channel has an edge substantially parallel to an outer edge of the data conductive layer including the source electrode 173 and disposed outside an outer edge of the source electrode 173. Also, the semiconductor 154 has a self-aligned structure with an edge of the data conductive layer including the source electrode 173. As a result, the size of the transistor Q may be reduced.

A first insulating layer 180a may be disposed on the data conductive layer and a plurality of color filters 230 may be disposed on the first insulating layer 180a. The color filters 230 may display one of primary colors such as three primary colors of red, green, and blue, or four primary colors. A plurality of color filters representing different primary colors may be alternately arranged in the first direction DR1 in a plan view.

The color filter 230 may have an opening 235 disposed over the expanded portion 177 of the drain electrode 175.

Two adjacent color filters 230 may overlap each other at a boundary between two neighboring pixels PX in the first direction DR1.

A second insulating layer 180b may be disposed on the color filter 230.

The first insulating layer 180a and the second insulating layer 180b may include an inorganic insulating material and/or an organic insulating material such as a silicon nitride, a silicon oxide, a silicon oxynitride, etc. For example, the first insulating layer 180a may include an inorganic insulating material, and the second insulating layer 180b may include an organic insulating material. In this case, the upper surface of the second insulating layer 180b may be substantially flat. The second insulating layer 180b may serve as an overcoat layer for the color filter 230 to prevent the color filter 230 from being exposed and impurities such as pigments included in the color filter 230 from flowing into a liquid crystal layer 3.

The first insulating layer 180a and the second insulating layer 180b may have an opening 185 disposed on the expanded portion 177 of the drain electrode 175 and overlapping the expanded portion 177. In a plan view, the opening 185 may be disposed in the opening 235 of the color filter 230.

A plurality of pixel electrodes 191 may be disposed on the second insulating layer 180b. The pixel electrode 191 may include a transparent conductive material such as indium-tin oxide (ITO), indium-zinc oxide (IZO), a metal thin film, etc.

Referring to FIG. 1, the overall shape of each pixel electrode 191 may be, for example, a substantially rectangular shape, and a portion of the pixel electrode 191 may be removed in some embodiments.

In detail, the pixel electrode 191 may include a transverse stem 192, a longitudinal stem 193, a plurality of branches 194, and an expanded portion 197.

The transverse stem 192 generally extends in the direction parallel to the first direction DR1, and the longitudinal stem 193 generally extends in the direction parallel to the second direction DR2 to cross the transverse stem 192. The transverse stem 192 and the longitudinal stem 193 intersecting and connected to each other may together form a cross shape.

The plurality of branches 194 are protruded from the transverse stem 192 or the longitudinal stem 193. The plurality of branches 194 may extend obliquely to the first direction DR1 and the second direction DR2. Portions of the pixel electrode 191 between the adjacent branches 194 may be removed, thereby forming a slit.

The expanded portion 197 of the pixel electrode 191 may overlap the expanded portion 177 of the drain electrode 175 in a plan view. The expanded portion 197 is electrically connected to the expanded portion 177 of the drain electrode 175 through the opening 185 of the first and second insulating layers 180a and 180b, and the pixel electrode 191 receives the data voltage via the drain electrode 175.

The shape of the pixel electrode 191 is not limited to the example illustrated in FIG. 1, and may have various shapes without departing from the scope of the present disclosure.

Referring to FIG. 2 and FIG. 3, the display device according to an embodiment of the present disclosure may be a liquid crystal display, and may include a first display panel 100 and a second display panel 200 facing each other and a liquid crystal layer 3 disposed between the first and second display panels 100 and 200. The first display panel 100 may include the first substrate 110 on which the above-described transistor Q, the pixel electrode 191, and the like are formed, and the second display panel 200 may include a second substrate 210. Herein, for the convenience of description with reference to FIG. 2 and FIG. 3, the term ‘up’ or ‘above’ with respect to the first substrate 110 refers to an upper side of the surface toward the liquid crystal layer 3 among the two surfaces of the first substrate 110, and the term ‘down’ or ‘under’ with respect to the second substrate 210 refers to a lower side of the surface toward the liquid crystal layer 3 among the two surfaces of the second substrate 210.

Referring to the second display panel 200, a light blocking member 220 may be disposed under the second substrate 210.

The light blocking member 220 may be disposed between the pixel electrodes 191 adjacent in the second direction DR2 to prevent light leakage between the adjacent pixel electrodes 191. The light blocking member 220 may overlap the pixel circuit including the transistor Q.

Meanwhile, the longitudinal portion 133 of the storage electrode line 131 described above may overlap most of the space between two pixel electrodes 191 neighboring in the first direction DR1, thereby preventing light leakage between the pixel electrodes 191 adjacent in the first direction DR1.

The light blocking member 220 and the longitudinal portion 133 of the storage electrode line 131 may have a light shielding portion having a lattice shape. The light shielding portion may prevent light leakage between the adjacent pixels PX. The display element of each pixel PX may be a display area in which light may be displayed as being surrounded by the light blocking member and the light shielding portion.

An insulating layer 250 may be disposed under the light blocking member 220, and a common electrode 270 may be disposed under the insulating layer 250.

The insulating layer 250 may include an inorganic insulating material and/or an organic insulating material. The insulating layer 250 may prevent the light blocking member 220 from being exposed, and may prevent a material such as carbon black included in the light blocking member 220 from flowing into the liquid crystal layer 3.

The common electrode 270 may be continuously formed on the lower surface of the second substrate 210. The common electrode 270 may include a transparent conductive material such as ITO or IZO, or a metal such as aluminum, silver, chromium, or an alloy thereof.

Unlike the above description, the color filter 230 may be disposed between the second substrate 210 and the common electrode 270 in some embodiments.

The liquid crystal layer 3 may include liquid crystal molecules 31 having dielectric anisotropy. For example, the liquid crystal molecules 31 may be oriented such that their major axes are substantially aligned perpendicular or at an acute angle with respect to the surfaces of the substrates 110 and 210 in the absence of an electric field in the liquid crystal layer 3.

A first alignment layer 11 may be disposed on the pixel electrode 191 and the second insulating layer 180b, and a second alignment layer 21 may be disposed under the common electrode 270. The first and second alignment layers 11 and 21 may be vertical alignment layers.

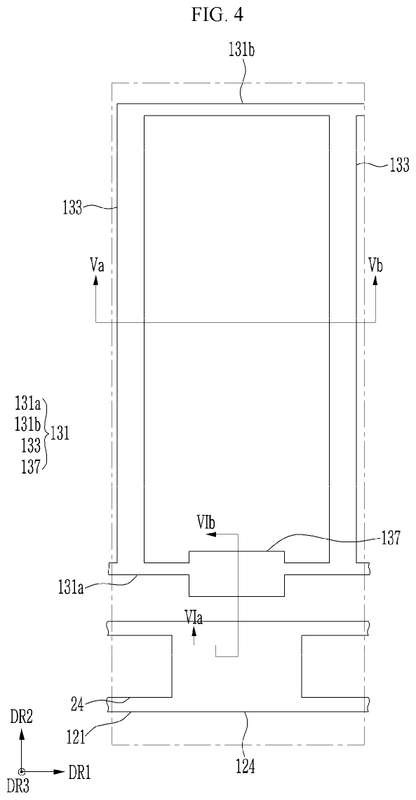

Next, the manufacturing method of the display device according to an embodiment of the present disclosure is described with reference to FIG. 4 to FIG. 20 with reference to FIG. 1 to FIG. 3 described above.

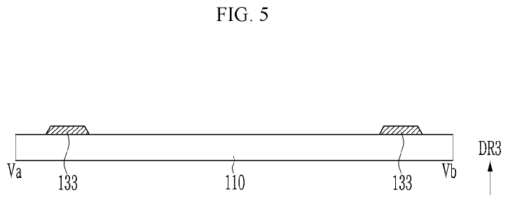

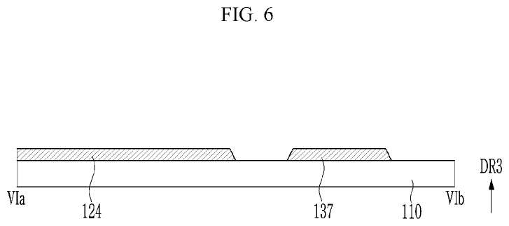

FIG. 4 is a layout view of a display device in an example process of a manufacturing method of a display device according to an embodiment of the present disclosure, FIG. 5 is a cross-sectional view of the display device shown in FIG. 4 taken along a line Va-Vb, and FIG. 6 is a cross-sectional view of the display device shown in FIG. 4 taken along a line VIa-VIb,

Referring to FIG. 4 to FIG. 6, a gate conductive layer including a gate line 121 and a storage electrode line 131 is formed by stacking (or depositing) and patterning a conductive material such as a metal on a first substrate 110 by sputtering or the like. The patterning method may use a photolithography process of etching the conductive layer by using a photoresist mask.

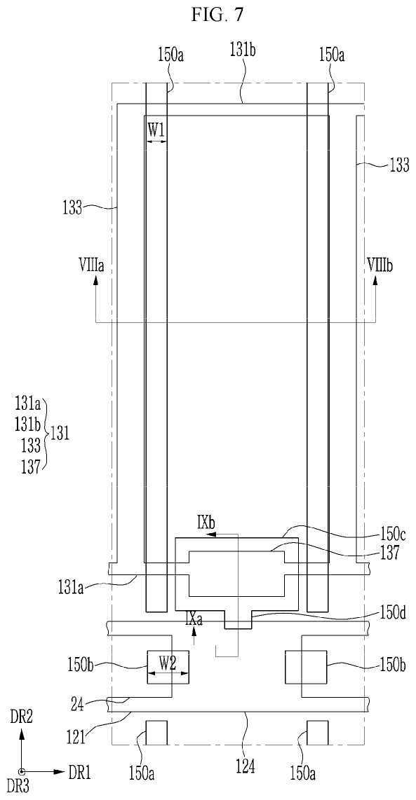

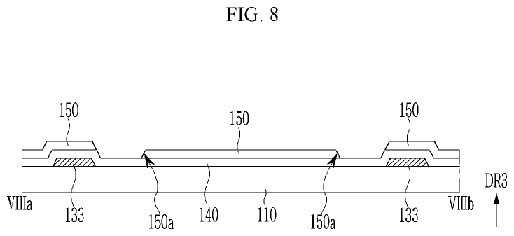

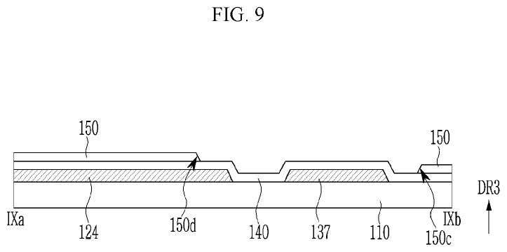

FIG. 7 is a layout view of a display device in an example process at a later stage to that of the display device shown in FIG. 4, FIG. 8 is a cross-sectional view of a display device shown in FIG. 7 taken along a line VIIIa-VIIIb, and FIG. 9 is a cross-sectional view of a display device shown in FIG. 7 taken along a line IXa-IXb.

Referring to FIG. 7 to FIG. 9, a gate insulating layer 140 is formed by stacking (or depositing) an insulating material such as a silicon nitride (SiNx), a silicon oxide (SiOx), or a silicon oxynitride on the first substrate 110 on which the gate conductive layer is formed.

Next, a semiconductor layer 150 is formed by stacking (or depositing) a semiconductor material such as amorphous silicon, polycrystalline silicon, a metal oxide, and the like on the gate insulating layer 140. Next, the semiconductor layer 150 is patterned to form a plurality of openings 150a, 150b, and 150c. The patterning method may use a photolithography process for etching the semiconductor layer 150 by using a photoresist mask. This may be referred to as first etching of the semiconductor layer 150.

The opening 150a may correspond to the data line 171 to be formed. The opening 150a may extend substantially in the second direction DR2 along a region to form the data line 171 and have a width W1 in the first direction DR1 that is larger than a width of the data line 171.

The opening 150a may not overlap the gate line 121 in a plan view as shown in FIG. 7. However, the opening 150a may cross the gate line 121 and extend in the second direction DR2.

The opening 150b may correspond to the pixel circuit and disposed between two openings 150a adjacent in the second direction DR2 in the plan view. The opening 150b may be spaced apart from the opening 150a. In another embodiment, the opening 150b may be connected to the opening 150a.

The width W2 of the opening 150b in the first direction DR1 may be larger than the width W1 of the opening 150a in the first direction DR1. According to another embodiment, the width W2 of the opening 150b in the first direction DR1 may be equal to the width W1 of the opening 150a in the first direction DR1.

The opening 150c may be disposed between two openings 150a adjacent in the first direction DR1. The openings 150c may be spaced apart from the adjacent openings 150a. In another embodiment, the openings 150c may be connected to one or more of the adjacent openings 150a. The opening 150c may be disposed corresponding to the expanded portion 177 of the drain electrode 175 to be formed.

The semiconductor layer 150 that is patterned may further include an opening 150d protruded from one side (e.g., the lower side) of the opening 150c. The opening 150d may correspond to at least a part of the bar-shape portion of the drain electrode 175 to be formed.

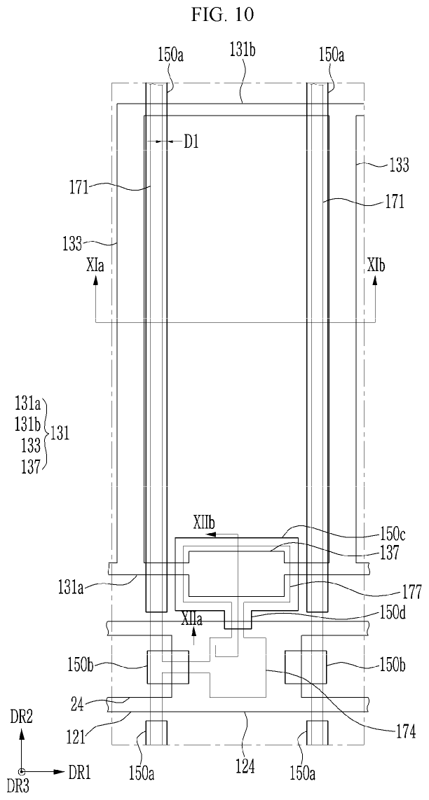

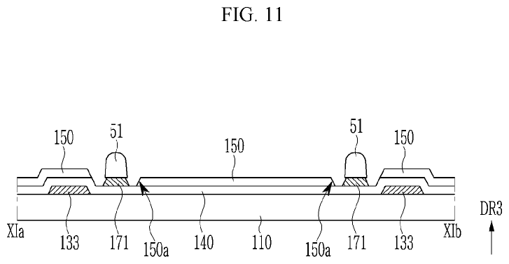

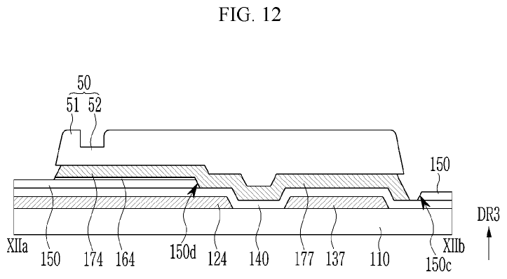

FIG. 10 is a layout view of a display device in an example process at a later stage to that of the display device shown in FIG. 7, FIG. 11 is a cross-sectional view of the display device shown in FIG. 10 taken along a line XIa-XIb, and FIG. 12 is a cross-sectional view of the display device shown in FIG. 10 taken along a line XIIa-XIIb.

Referring to FIG. 10 to FIG. 12, an n-type impurity is doped on the semiconductor layer 150 to form an ohmic contact layer 164, and a conductive material such as a metal is deposited by a method such as sputtering and patterned to form a data conductive layer including a data line 171 and an electrode 174. The patterning method may use a photolithography process for performing the etching by using a photoresist mask.

In an exemplary photolithography process of the data conductive layer, a photosensitive material such as a photoresist and the like is coated on the deposited conductive material, and the photosensitive material layer is exposed by using a half-tone photomask. Accordingly, a mask pattern 50 having different thicknesses is formed. The mask pattern 50 may include a first portion 51 and a second portion 52 having a thinner thickness than that of the first portion 51. The second portion 52 may be formed corresponding to the channel of the above-described transistor Q.

The deposited conductive material is etched by using the mask pattern 50 as a mask to form the data conductive layer including the data line 171 and the electrode 174 as shown in FIG. 10 to FIG. 12. The electrode 174 may include the source electrode 173 and the drain electrode 175 described above, and a portion corresponding to the channel between the source electrode 173 and the drain electrode 175.

The gap D1 between an edge of the data line 171 and an edge of the opening 150a of the semiconductor layer 150 may be greater than zero, for example, about 1.5 micrometers or more and about 2.5 micrometers or less. Similarly, the gap between an edge of the expanded portion 177 included in the drain electrode 175 and an edge of the opening 150c of the semiconductor layer 150 may be greater than zero, for example, about 1.5 micrometers or more and about 2.5 micrometers or less.

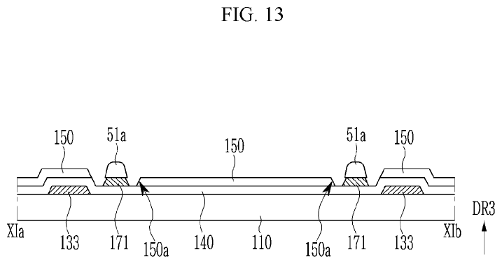

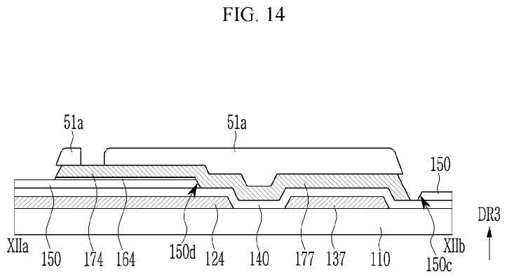

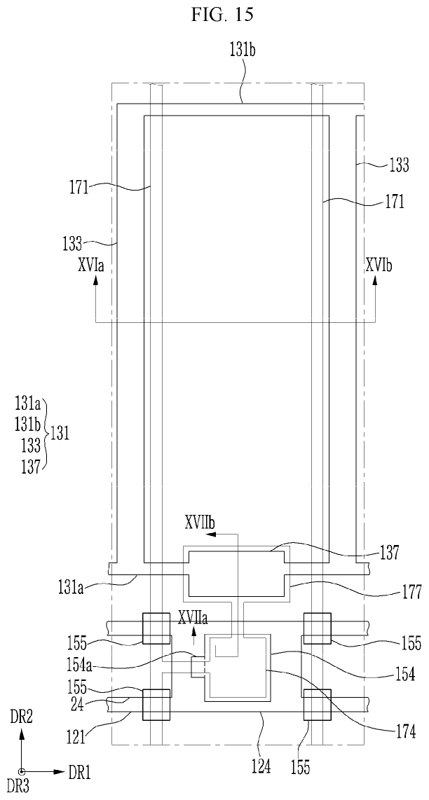

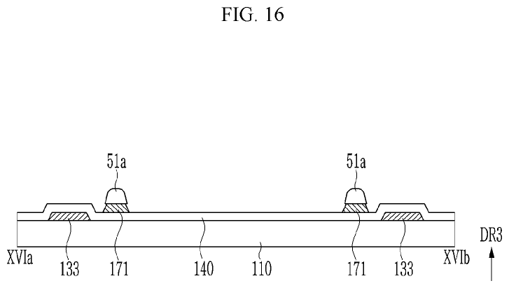

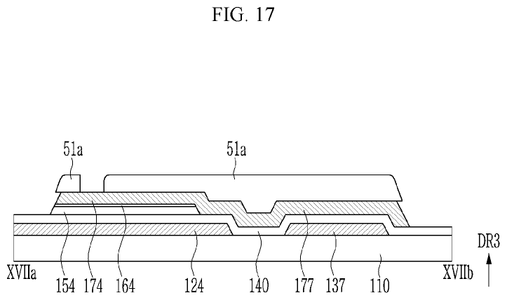

FIG. 13 is a layout view of a display device in an example process at a later stage to that of the display device shown in FIG. 11, and FIG. 14 is a layout view of a display device in an example process at a later stage to that of the display device shown in FIG. 12. FIG. 15 is a layout view of a display device in an example process at a later stage to that of the display device shown in FIG. 10, FIG. 16 is a cross-sectional view of the display device shown in FIG. 15 taken along a line XVIa-XVIb, and FIG. 17 is a cross-sectional view of a display device shown in FIG. 15 taken along a line XVIIa-XVIIb.

Referring to FIG. 13 and FIG. 14, the mask pattern 50 is etched (etched back) to remove the second portion 52 of the mask pattern 50 to form a first portion 51a having a thinned thickness.

Next, referring to FIG. 15 to FIG. 17, the semiconductor layer 150 is secondarily etched by using the first portion 51a of the mask pattern 50 as a mask. Portions of the semiconductor layer 150 that are not covered by the first portion 51a of the mask pattern 50 are removed, and accordingly the semiconductor layer 150 of a slightly larger area than the data conductive layer may remain. Accordingly, the semiconductor layer 150 including the semiconductor 154, the semiconductor 155, and the protruded portion 154a may be formed.

According to one embodiment, the size and shape of the protruded portion 154a may vary according to the size and shape of the opening 150b of the semiconductor layer 150. For example, the protruded portion 154a may not be formed if the right edge of the opening 150b is disposed near the edge of the electrode 174. In the present embodiment where the right edge of the opening 150b is sufficiently spaced apart from the edge of the electrode 174, the protruded portion 154a may be formed as shown in FIG. 15.

In another embodiment, the semiconductor layer 150 including the semiconductor 154, the semiconductor 155, and the protruded portion 154a may be formed by etching the semiconductor layer 150 by using the mask pattern 50 before removing the second portion 52 as a mask.

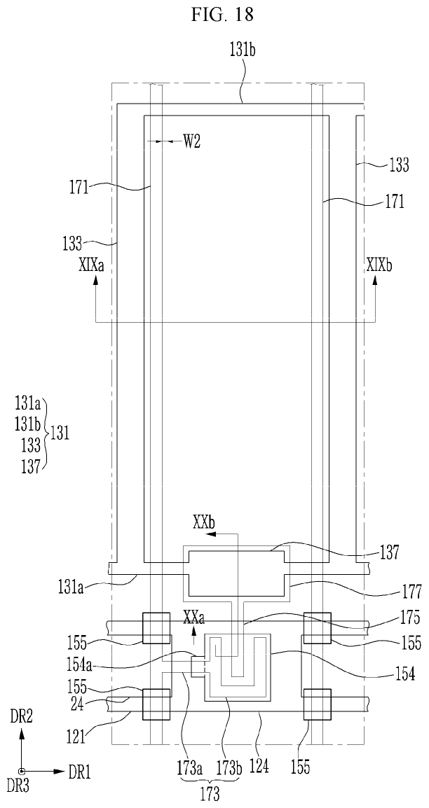

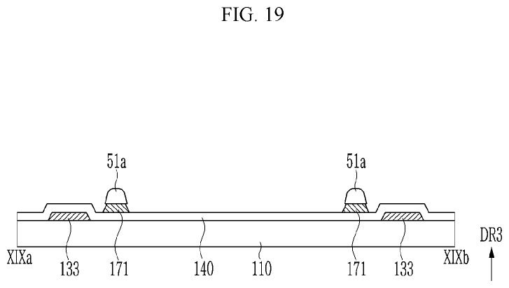

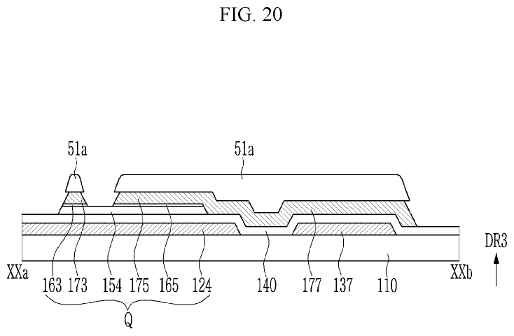

FIG. 18 is a layout view of a display device in an example process at a later stage to that of the display device shown in FIG. 15, FIG. 19 is a cross-sectional view of the display device shown in FIG. 18 taken along a line XIXa-XIXb, and FIG. 20 is a cross-sectional view of the display device shown in FIG. 18 taken along a line XXa-XXb.

Referring to FIG. 18 to FIG. 20, the electrode 174 of the data conductive layer is etched by using the first portion 51a of the mask pattern 50 as a mask to form the source electrode 173 and the drain electrode 175 that are spaced apart from each other and facing via the channel of the transistor Q. Next, the ohmic contact layer 164 is etched to form ohmic contact layers 163 and 165 between the semiconductor 154 and the source electrode 173, and the semiconductor 154 and the drain electrode 175.

Accordingly, the transistor Q as illustrated in and described with reference to FIG. 1 to FIG. 3 is formed. As such, the semiconductor 154 may be patterned using the same mask pattern 50 used for patterning the source electrode 173 and the drain electrode 175 or the first portion 51a of the mask pattern 50. Accordingly, the semiconductor 154 in which the channel of the transistor Q is formed does not have a separate island form from the source electrode 173 and the drain electrode 175, and the semiconductor 154 may have an edge substantially parallel to the outer side of the data conductive layer including the source electrode 173 and disposed outside the outer edge of the source electrode 173. That is, the semiconductor 154 has a structure that is self-aligned with the edge of the data conductive layer including the source electrode 173. Since an alignment margin between the semiconductor 154 and the source electrode 173, and between the semiconductor 154 and the drain electrode 175 (or the electrode 174) does not have to be considered, the size of the transistor Q may be reduced.

In a conventional manufacturing process, the semiconductor 154 and the data conductive layer are etched together using one mask pattern, and the semiconductor layer may remain under the data line 171 included in the data conductive layer. According to the embodiment of the present disclosure, the semiconductor layer 150 is first etched to remove a portion under the data line 171 and the expanded portion 177 of the drain electrode 175, and the semiconductor layer 150 is secondarily etched by using the mask pattern 50 for patterning the electrode 174 or the source electrode 173 and the drain electrode 175. Therefore, the semiconductor 154 in which the channel is formed may be self-aligned with the electrode 174 or the source electrode 173 and the drain electrode 175. Therefore, the present display device may reduce or eliminate a concern associated with an alignment margin between the semiconductor 154 and the source electrode 173, and between the semiconductor 154 and the drain electrode 175 (or the electrode 174). Further, the size of the transistor Q may be reduced while preventing a light influence and a display defect by the semiconductor layer 150 under the data line 171.

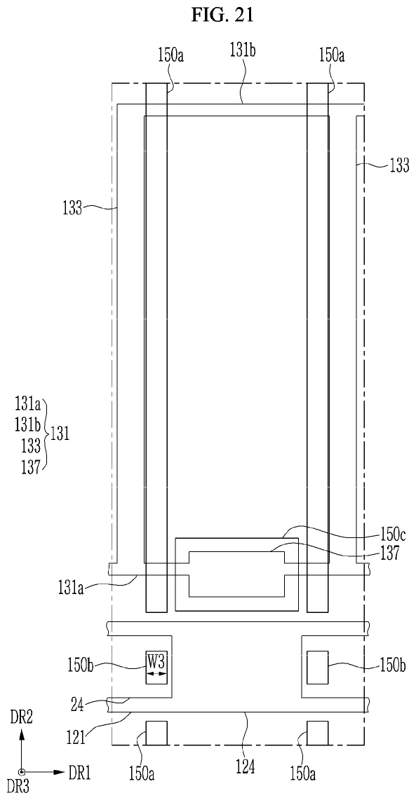

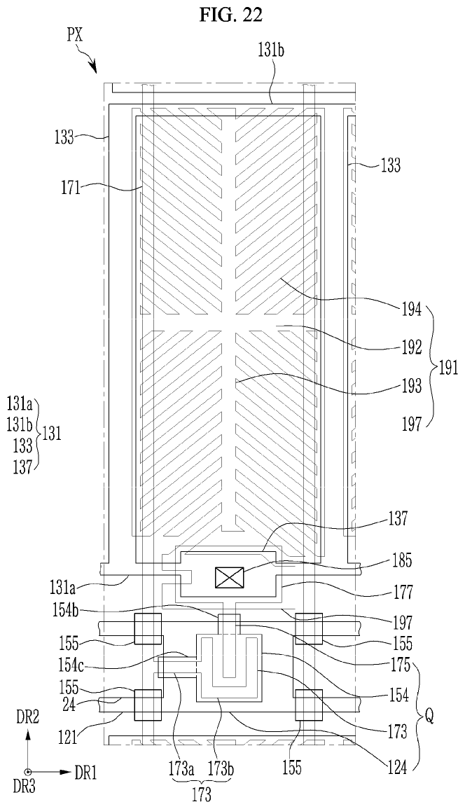

Next, a method of manufacturing the display device according to an embodiment of the present disclosure and the display device formed thereby are described with reference to FIG. 21 and FIG. 22 along with the drawings described above.

FIG. 21 is a layout view of a display device in an example process of a manufacturing method of a display device according to an embodiment of the present disclosure, and FIG. 22 is a layout view of a pixel PX of a display device according to an embodiment of the present disclosure.

Referring to FIG. 21, the opening 150d of the semiconductor layer 150 illustrated in FIG. 7 described above may be omitted. The semiconductor layer 150 of the display device thus formed may have a protruded portion 154b protruding from an upper side of the semiconductor 154 as shown in FIG. 22. The protruded portion 154b may overlap at least a portion of a rod-shaped portion of the drain electrode 175 that does not overlap the semiconductor 154. The protruded portion 154b may have an edge that is disposed outside and parallel to an edge of at least the part of the rod-shaped portion of the drain electrode 175 that does not overlap the semiconductor 154.

The protruded portion 154b may overlap a portion where the rod-shaped portion of the drain electrode 175 and the gate line 121 cross each other. A short circuit defect between the drain electrode 175 and the gate line 121 may occur due to a step of the gate line 121 at a portion where the rod-shaped portion of the drain electrode 175 intersects the edge of the gate line 121. However, according to the present embodiment, since the protruded portion 154b is disposed at the intersection of the bar-shape portion of the gate line 121 and the drain electrode 175, a short circuit defect between the drain electrode 175 and the gate line 121 may be prevented.

In the present embodiment, the shape or size of the opening 150b of the semiconductor layer 150 may be different from those formed in the process illustrated in FIG. 7 to FIG. 9. In the embodiment shown in FIG. 21, the width W3 of the opening 150b in the first direction DR1 may be smaller than the width W2 of the opening 150b in the first direction DR1 shown in FIG. 7.

As illustrated in FIG. 22, the semiconductor layer 150 of the display device has a protruded portion 154c that is longer than the length in the first direction DR1 than the protruded portion 154a in the first direction DR1 illustrated in FIG. 1 to FIG. 3. As illustrated in FIG. 22, the protruded portion 154c may have a shape protruded from one side of the semiconductor 154. The protruded portion 154c may overlap a part adjacent to the curved portion 173b among the straight line portion 173a of the source electrode 173, and may have an edge parallel to an edge of the part adjacent to the curved portion 173b among the straight line portion 173a of the source electrode 173 and disposed outside.

The protruded portion 154c may also overlap an edge of the opening 24 of the gate line 121 or an edge of the gate electrode 124. That is, the protruded portion 154c may overlap a portion where the straight line portion 173a of the source electrode 173 and the edge of the opening 24 or the edge of the gate electrode 124 cross each other. At the portion where the straight line portion 173a of the source electrode 173 and the edge of the opening 24 or the edge of the gate electrode 124 cross each other, a short circuit defect may occur between the source electrode 173 and the gate line 121 due to a step of the gate conductive layer. However, according to the present embodiment, since the protruded portion 154c is disposed at the cross region of the straight line portion 173a of the source electrode 173 and the edge of the opening 24 or the edge of the gate electrode 124, a short circuit defect between the source electrode 173 and the gate line 121 may be prevented.

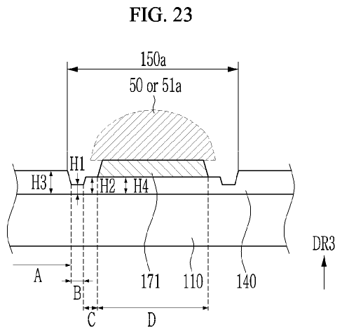

Next, a structure around the data line 171 of the display device according to an embodiment of the present disclosure is described with reference to FIG. 23 along with the drawings described above.

FIG. 23 is a cross-sectional view of surroundings of a data line of a display device according to an embodiment of the present disclosure,

Referring to FIG. 23, in the display device formed by the method of manufacturing the display device according to the embodiment as described above, the thickness of the gate insulating layer 140 under and around the data line 171 may vary depending on a position.

In FIG. 23, a region overlapping the data line 171 is referred to as a region D, a region disposed outside the region D and overlapping the mask pattern 50 or the first portion 51a is referred to as a region C, a region that is disposed outside the region C and does not overlap the mask pattern 50 or the first portion 51a is referred to as a region B, and a region disposed directly outside the region B is referred to as a region A.

The region B, the region C, and the region D shown in FIG. 23 are included in the opening 150a formed by the first etching the semiconductor layer 150 in the manufacturing process described with reference to FIG. 7 to FIG. 9. In a step of forming the opening 150a, when the semiconductor layer 150 corresponding to the region B, the region C, and the region D is first etched, a part of the gate insulating layer 140 may be etched. Accordingly, the thickness of the gate insulating layer 140 in the region B, the region C, and the region D may be thinner than that of the gate insulating layer 140 in the region A.

In the region B and the region C shown in FIG. 23, in the process of forming the data conductive layer including the data line 171 and the electrode 174, a part of the gate insulating layer 140 around the data line 171 may be etched. In this case, the gate insulating layer 140 of the region A may not be etched due to the semiconductor layer 150.

The region A and the region B shown in FIG. 23 correspond to the regions where the semiconductor layer 150 is secondarily etched by using the mask pattern 50 or the first portion 51a of the etch mask pattern 50 as a mask in the manufacturing process described with reference to FIG. 15 to FIG. 17. Therefore, a portion of the gate insulating layer 140 corresponding to the region A and the region B may be etched. Therefore, the thicknesses of the regions A and B of the gate insulating layer 140 may be thinned. Further, in the manufacturing process described with reference to FIG. 18 to FIG. 20, a part of the gate insulating layer 140 corresponding to the regions A and B may be etched in the process of etching the ohmic contact layer 164 by using the first portion 51a of the mask pattern 50 as a mask.

Therefore, in a plan view, the thickness H1 of the gate insulating layer 140 corresponding to the region B that is spaced apart from the data line 171 may be thinner than the thicknesses H2, H3, and H4 of the gate insulating layer 140 corresponding to the regions A, C, and D. The thickness H3 of the gate insulating layer 140 corresponding to the region A may be greater than, smaller than, or equal to the thickness H2 of the gate insulating layer 140 corresponding to the region C. The thickness H4 of the gate insulating layer 140 corresponding to the region D may be slightly greater than or equal to the thickness H2 of the gate insulating layer 140 corresponding to the region C.

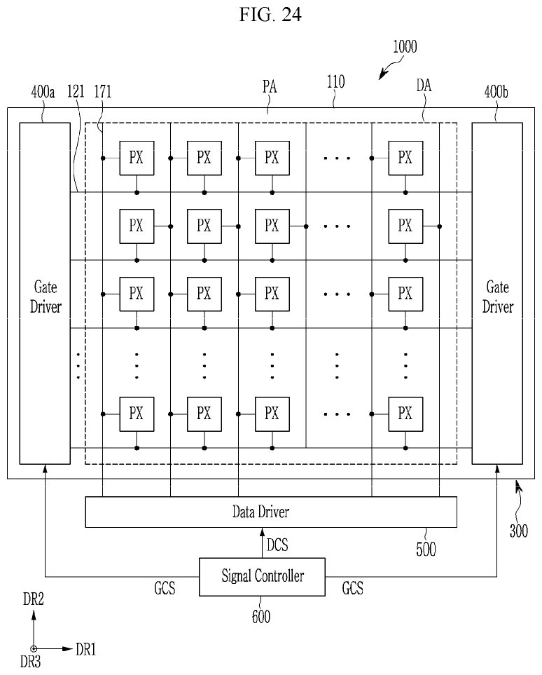

Next, a display device according to an embodiment of the present disclosure is described with reference to FIG. 24.

FIG. 24 is a layout view of a display device according to an embodiment of the present disclosure.

Referring to FIG. 24, the display device 1000 according to an embodiment of the present disclosure includes a display panel 300 including a display area DA and a peripheral area PA disposed outside the display area DA. The display panel 300 includes the first substrate 110 described above with reference to FIG. 1 to FIG. 3.

The display area DA corresponds to a region of the display panel 300 capable of displaying an image according to an input image signal, and includes a plurality of pixels PX, a plurality of gate lines 121, and a plurality of data lines 171.

The pixel PX corresponds to a unit for displaying the image, and each pixel PX may include at least one transistor (e.g., transistor Q) as described above and a pixel electrode 191 electrically connected to the transistor. The plurality of pixels PX may be arranged in the display panel 300, for example, in a matrix form.

Each pixel PX may display one of primary colors, and an image of a desired color may be recognized by a spatial and temporal sum of these primary colors. The primary color may include, for example, three primary colors including red, green, and blue, and may further include white.

The gate line 121 may transmit a gate signal including a gate-on voltage and a gate-off voltage. The plurality of gate lines 121 may generally be sequentially arranged side by side in the second direction DR2, and each of the gate lines 121 may extend in the first direction DR1.

The data line 171 may transmit a data voltage corresponding to the input image signal. The plurality of data lines 171 may be generally arranged in a direction parallel to the first direction DR1, and each of the data lines 171 may generally extend in the second direction DR2.

Referring to FIG. 24, the transistors (for example, the transistor Q described above) included in the plurality of pixels PX disposed in one pixel column extending in the second direction DR2 may be alternately electrically connected two data lines 171. For example, the transistors of the plurality of pixels PX of each pixel column may be alternately connected to two data lines 171 by a unit of one pixel row (or periodically). According to another embodiment, the transistors of the plurality of pixels PX of each pixel column may be alternately connected to two data lines 171 by a unit (or period) of two or more pixel rows.

According to another embodiment, the plurality of pixels PX disposed in one pixel column may be electrically connected to the same data line 171.

The peripheral area PA may correspond to an area that mostly does not display the image, and is adjacent to the surroundings of the display area DA. For example, the peripheral area PA may surround the display area DA.

The peripheral area PA may include gate drivers 400a and 400b.

The gate drivers 400a and 400b may be electrically connected to the plurality of gate lines 121 to apply the gate signal. FIG. 24 illustrates an example in which the first gate driver 400a is disposed in the peripheral area PA on the left side of the display area DA, and the second gate driver 400a is disposed in the peripheral area PA on the right side of the display area DA. The gate drivers 400a and 400b may generate the gate signal including the gate-on voltage and the gate-off voltage, and may sequentially apply the gate signals to the plurality of gate lines 121 in the direction parallel to the second direction DR2.

The gate drivers 400a and 400b may include a transistor that may be formed directly in the peripheral area PA together with the transistor Q of the pixel PX disposed in the display area DA in the same process and wires or electrodes that may be disposed on the same layer as the data line 171. Accordingly, at least one transistor included in the gate drivers 400a and 400b and the wiring or the electrode connected to the at least one transistor and disposed on the same layer as the data line 171 may have the substantially similar structure and characteristics as the transistor Q and the data line 171 shown in FIG. 1 to FIG. 3.

In another embodiment, one of the first and second gate drivers 400a and 400b may be omitted.

The display device 1000 may include a data driver 500 and a signal controller 600.

The data driver 500 is electrically connected to the plurality of data lines 171. The data driver 500 may selectively apply the data voltage, which is a gray voltage corresponding to the input image signal, to the corresponding data line 171 under the control of the signal controller 600.

The signal controller 600 may control the gate drivers 400a and 400b and the data driver 500 by providing control signals (e.g., a gate control signal (GCS), a data control signal (DCS)) to the gate drivers 400a and 400b and the data driver 500.

The data driver 500 and/or the signal controller 600 may be mounted to the peripheral area PA of the display panel 300 in a form of a plurality of driving chips, or may be mounted on a flexible printed circuit film or a printed circuit board (PCB) that is electrically connected to the display panel 300.

Referring to FIG. 24 together with FIG. 1 described above, the transistors Q included in the plurality of pixels PX disposed in one pixel column may be electrically connected to two data lines 171 alternately. In a case where the semiconductor 154 is not formed to be aligned with the edge of the data conductive layer including the source electrode 173 and is formed through a separate mask pattern, misalignment of the semiconductor 154 for the data conductive layer including the source electrode 173 may occur. The misalignment may cause a difference in characteristics such as a kickback voltage between the transistor Q connected to the data line 171 on the left side and the transistor Q connected to the data line 171 on the right side based on one pixel column. Herein, the kickback voltage refers to a change in the voltage of the output terminal of the transistor Q according to the change of the gate signal applied to the gate terminal of the transistor Q. As a result, display defects such as horizontal streaks may occur due to the misalignment. However, according to the present embodiment, the semiconductor 154 has the structure that is self-aligned with an edge of the data conductive layer including the source electrode 173, and the display device 1000 may prevent a characteristic dispersion such as the kickback voltage in the connection structure of the pixel PX and the data line 171.

While the present disclosure has been described in connection with what is presently considered to be exemplary embodiments, it is to be understood that the present disclosure is not limited to the disclosed exemplary embodiments. On the contrary, it is intended to cover various modifications and equivalent arrangements included within the spirit and scope of the present disclosure including the appended claims.

<Description of symbols>

| | |
|---|---|
| 3: liquid crystal layer | 11, 21: alignment layer |
| 24, 150a, 150b, 150c, | |
| 150d, 185, 235: opening | |
| 31: liquid crystal molecule | 50: mask pattern |
| 100, 200, 300: display panel | 110, 210: substrate |
| 121: gate line | 131: storage electrode line |
| 137, 177, 197: expanded portion | 140: gate insulating layer |
| 150: semiconductor layer | 154, 155: semiconductor |
| 154a, 154b, 154c: protruded portion | 163, 164, 165: ohmic contact layer |
| 171: data line | 173: source electrode |
| 175: drain electrode | 180a, 180b, 250: insulating layer |
| 191: pixel electrode | 220: light blocking member |
| 230: color filter | 270: common electrode |
| 400a, 400b: gate driver | 500: data driver |
| 600: signal controller | 1000: display device |

What is claimed is:

1. A display device comprising:
a substrate;
a gate insulating layer disposed on the substrate;
a semiconductor layer disposed on the gate insulating layer and including a first semiconductor;
a source electrode and a drain electrode disposed on the first semiconductor; and
a data line disposed on the gate insulating layer,
wherein the gate insulating layer includes a first portion overlapping the data line in a plan view and a second portion disposed adjacent to the first portion, and
wherein the second portion is thinner than the first portion.

2. The display device of claim 1, wherein the first semiconductor has an edge parallel to an edge of the source electrode and disposed outside the edge of the source electrode in the plan view.

3. The display device of claim 2, wherein the gate insulating layer is disposed between the data line and the substrate, and the semiconductor layer is absent in an area where the gate insulating layer is disposed between the data line and the substrate.

4. The display device of claim 3, further comprising a gate line disposed on the substrate and crossing the data line,
wherein the semiconductor layer further includes a second semiconductor disposed at a region where the gate line and the data line cross each other.

5. The display device of claim 3, wherein the source electrode includes a straight line portion extending in a direction different from an extending direction of the data line and a curved portion extending from the straight line portion,
wherein the semiconductor layer further includes a first protruded portion having a shape protruded from one side of the first semiconductor, and
wherein the first protruded portion of the semiconductor layer overlaps at least a part of the straight line portion of the source electrode.

6. The display device of claim 5, wherein the first protruded portion of the semiconductor layer has an edge parallel to an edge of the part of the straight line portion of the source electrode.

7. The display device of claim 6, further comprising a gate line disposed on the substrate and crossing the data line,
wherein the gate line includes a gate electrode, and
wherein the first protruded portion of the semiconductor layer overlaps an edge of the gate electrode.

8. The display device of claim 6, further comprising a gate line disposed on the substrate and crossing the data line,
wherein the semiconductor layer further includes a second protruded portion having a shape protruded from one side of the first semiconductor, and
wherein the second protruded portion of the semiconductor layer overlaps an edge of the gate line.

9. The display device of claim 8, wherein the second protruded portion of the semiconductor layer has an edge parallel to an edge of at least a first portion of the drain electrode away from a second portion that overlaps the first semiconductor.

10. The display device of claim 8, further comprising a storage electrode disposed between the substrate and the gate insulating layer,
wherein the drain electrode includes an expanded portion overlapping the storage electrode, and
wherein the semiconductor layer is absent between the expanded portion of the drain electrode and the substrate.

11. A display device comprising:
a substrate;
a gate line disposed on the substrate;
a gate insulating layer disposed on the gate line;
a semiconductor layer disposed on the gate insulating layer and including a first semiconductor;
a source electrode and a drain electrode that are disposed on the first semiconductor; and
a data line disposed on the gate insulating layer,
wherein the first semiconductor has an edge parallel to an edge of the source electrode and disposed outside the edge of the source electrode in a plan view,
wherein the semiconductor layer is absent between the data line and the substrate, and
wherein the semiconductor layer further includes a second semiconductor disposed at a region where the gate line and the data line cross each other.

12. The display device of claim 11, wherein the source electrode includes a straight line portion extending in a direction different from an extending direction of the data line and a curved portion extending from the straight line portion,
wherein the semiconductor layer further includes a first protruded portion having a shape protruded from one side of the first semiconductor, and
wherein the first protruded portion of the semiconductor layer overlaps at least a part of the straight line portion of the source electrode.

13. The display device of claim 12, wherein the first protruded portion of the semiconductor layer has an edge parallel to an edge of the part of the straight line portion of the source electrode.

14. The display device of claim 13, wherein the gate line includes a gate electrode, and
wherein the first protruded portion of the semiconductor layer overlaps an edge of the gate electrode.

15. The display device of claim 13, wherein the semiconductor layer further includes a second protruded portion having a shape protruded from one side of the first semiconductor, and
wherein the second protruded portion of the semiconductor layer overlaps an edge of the gate line.

16. The display device of claim 15, wherein the second protruded portion of the semiconductor layer has an edge parallel to an edge of at least a first portion of the drain electrode away from a second portion of the drain electrode that overlaps the first semiconductor.

17. A manufacturing method of a display device comprising:
forming a gate line including a gate electrode on a substrate;
forming a gate insulating layer on the gate line;
forming a semiconductor layer on the gate insulating layer and etching the semiconductor layer to form a first opening;
depositing a conductive material on the semiconductor layer to form a conductive layer and etching the conductive layer by using a first mask pattern to form a data line and an electrode; and
etching the semiconductor layer by using the first mask pattern or a second mask pattern that includes a portion of the first mask pattern,
wherein the data line is formed at a position overlapping the first opening, and
wherein an edge of the first opening and an edge of the data line are spaced apart from each other.

18. The manufacturing method of claim 17, wherein the first mask pattern includes a first portion and a second portion having different thicknesses from each other,
wherein the second mask pattern excludes the first portion that is thinner than the second portion, and
wherein the manufacturing method further comprising etching the electrode by using the second mask pattern to form a source electrode and a drain electrode facing each other.

19. The manufacturing method of claim 18, further comprising
forming a storage electrode line including a storage electrode on the substrate,
wherein a second opening is further formed in the semiconductor layer in the etching of the semiconductor layer to form the first opening,
wherein the drain electrode includes an expanded portion overlapping the storage electrode,
wherein the expanded portion is formed at a position overlapping the second opening, and
wherein an edge of the second opening and an edge of the expanded portion of the drain electrode are spaced apart from each other.

20. The manufacturing method of claim 18, wherein, in the etching of the semiconductor layer by using the first mask pattern or the second mask pattern, a first semiconductor having an edge parallel to an edge of the source electrode and disposed outside the edge of the source electrode in a plan view is formed.
